(19) United States
(12) Patent Application Publication
(10) Pub. No.: US 2024/0242968 A1
(43) Pub. Date: Jul. 18, 2024

(54) DICING GROOVE INSPECTING METHOD AND DICING METHOD

(71) Applicant: TOKYO SEIMITSU CO., LTD., Tokyo (JP)

(72) Inventors: Takashi TAMOGAMI, Hachioji-shi (JP); Yusuke KANESHIRO, Hachioji-shi (JP); Takeo TSUSHIMA, Hachioji-shi (JP)

(21) Appl. No.: 18/404,748

(22) Filed: Jan. 4, 2024

(30) Foreign Application Priority Data
Jan. 16, 2023 (JP) 2023-004679

(51) Int. Cl. H01L 21/304; H01L 21/67

(52) U.S. Cl. CPC H01L 21/3043; H01L 21/67288

(57) ABSTRACT

What is provided is a dicing groove inspecting method and a dicing method capable of improving wafer processing accuracy by measuring the inside of a groove.

The dicing groove inspecting method includes: forming an inspection groove by performing test cutting on a wafer using a dicing device equipped with an observation unit (MS) such that the inspection groove having a depth equal to or smaller than a measurement limit depth capable of measuring the inside of the inspection groove by the observation unit is formed on the wafer; and measuring the inside of the inspection groove formed on the wafer by the test cutting using the observation unit.

### BACKGROUND OF THE INVENTION

### Field of the Invention

The present invention relates to a dicing groove inspecting method and a dicing method and more particularly to a technique for inspecting kerfs (grooves) when dividing a wafer on which semiconductor devices or electronic components are formed into individual chips. Priority is claimed on Japanese Patent Application No. 2023-004679, filed Jan. 16, 2023, the content of which is incorporated herein by reference.

### Background

A dicing device (hereinafter, referred to as a dicer) that divides a wafer on which a device pattern of a semiconductor device or electronic component is formed into individual chips includes a blade which is rotated at a high speed by a spindle, a wafer table which holds a wafer by suction, and XYZθ drive units which change a relative position between the wafer table and the blade. In this dicer, a dicing process (cutting process) of the wafer is performed by cutting into the wafer with the blade while relatively moving the blade and the wafer using each drive unit.

When performing the dicing process on the wafer, a processing area is measured and an inspection (kerf check) of the processing area is performed on the basis of the measurement results in order to confirm the quality of the cutting line and the positional accuracy of the dicing grooves (for example, see Patent Documents 1 to 4). A common method of inspecting grooves after processing with a dicer is to detect defects from image data (for example, a grayscale image). When detecting defects from this grayscale image, the contrast between the defect and the surrounding area of the defect is important.

When measuring the grooves in three dimensions, it is possible to use a laser microscope or an interference microscope to observe the groove in three dimensions instead of an optical microscope. Here, since a measurement object has a minute shape of about 10 μm to 300 μm, three-dimensional measurement is performed using an image observed and captured by a microscope or a focused laser beam.

### PATENT DOCUMENTS

[Patent Document 1] Japanese Unexamined Patent Application, First Publication No. 2001-129822
[Patent Document 2] Japanese Unexamined Patent Application, First Publication No. 2015-085397
[Patent Document 3] Japanese Unexamined Patent Application, First Publication No. 2015-099026
[Patent Document 4] Japanese Unexamined Patent Application, First Publication No. 2022-037488

### SUMMARY OF THE INVENTION

As shown in FIG. 14, when measuring a groove g formed on a wafer W, the measurement state of the groove g is influenced by a ratio Dg/Wg (hereinafter, referred to as an aspect ratio) of a cut depth Dg to a width Wg of an opening of the groove g. When the cut depth Dg is deep relative to the width Wg of the opening of the groove g (in the case of the high aspect ratio), the inside of the groove g may not be measured.

For example, in step cutting which is one of processing methods in blade dicing, the wafer is processed in two steps of half cutting which processes a surface side of the wafer W and full cutting which processes the inside of a groove g1 formed by the half cutting and divides the chips by a groove g2. Here, since the measurement object is inside the groove g1 formed by the half cutting when inspecting the processing results of the groove g2 inside the groove g1 formed by the half cutting, the inner observation range of the illumination/laser beam focused by the objective lens will be limited if the width of the opening is narrow. Accordingly, the three-dimensional measurement range is limited.

The present invention has been made in view of such circumstances and an object thereof is to provide a dicing groove inspecting method and a dicing method capable of improving wafer processing accuracy by measuring and inspecting the inside of a groove.

In order to solve the above-described problems, a dicing groove inspecting method according to a first aspect of the present invention includes: forming an inspection groove by performing test cutting on a wafer using a dicing device equipped with an observation unit such that the inspection groove having a depth equal to or smaller than a measurement limit depth capable of measuring the inside of the inspection groove by the observation unit is formed on the wafer; and measuring the inside of the inspection groove formed on the wafer by the test cutting using the observation unit.

A dicing groove inspecting method according to a second aspect of the present invention is the dicing groove inspecting method according to the first aspect, and the depth of the inspection groove formed by the test cutting is determined according to an aspect ratio obtained in advance for the observation unit and corresponding to the ratio of the measurement limit depth to a width of the groove on the surface of the wafer.

A dicing method according to a third aspect of the present invention performs an adjustment work for the dicing device on the basis of a result obtained by measuring the inside of the inspection groove using the dicing groove inspecting method according to the first or second aspect and forms a dicing groove at a position of the wafer overlapping the inspection groove by main processing of the wafer.

A dicing method according to a fourth aspect of the present invention is the dicing method according to the third aspect, and the depth of the groove formed by the main processing is deeper than the depth of the inspection groove.

A dicing method according to a fifth aspect of the present invention is the dicing method according to the third aspect, when a first groove and a second groove which is narrower and deeper than the first groove are sequentially formed on the wafer in the main processing, the inspection groove includes a first inspection groove which has the same width as that of the first groove and has a depth equal to or smaller than the measurement limit depth according to a width of the first groove and a second inspection groove which has the same width as that of the second groove and is deeper than the first inspection groove, the first groove formed by the main processing of the wafer is formed to overlap the first inspection groove, and the depth of the first groove is deeper than the second inspection groove.

According to the present invention, since the inspection groove which is shallower than the measurement limit depth of the observation unit can be formed by the test cutting, it is possible to easily acquire the measurement result inside the inspection groove. Accordingly, it is possible to perform the main processing with high precision.

### BRIEF DESCRIPTION OF THE DRAWINGS

FIG. 1 is a graph showing characteristics of a blade thickness of a blade and a measurement limit depth inside a groove formed on a wafer.

FIG. 2 is a diagram showing the blade thickness of the blade and a measurement limit investigation result inside the groove formed on the wafer.

FIG. 3 is a perspective view showing a dicing device (blade dicer) according to a first embodiment of the present invention.

FIG. 4 is a cross-sectional view showing an outline of an observation unit.

FIG. 5 is a block diagram showing a control system of a dicing device according to the first embodiment of the present invention.

FIG. 6 is a diagram showing an output example of a groove inspection result by step cutting.

FIG. 7 is a cross-sectional view showing a dicing method according to Example 1.

FIG. 8 is a cross-sectional view showing a dicing method according to Example 2.

FIG. 9 is a block diagram showing a dicing device (laser dicer) according to a second embodiment of the present invention.

FIG. 10 is a cross-sectional view showing a dicing method according to Example 3.

FIG. 11 is a cross-sectional view showing a dicing method according to Example 4.

FIG. 12 is a cross-sectional view showing a dicing method according to Example 5.

FIG. 13 is a cross-sectional view showing a dicing method according to Example 6.

FIG. 14 is a cross-sectional view showing an example of forming a groove in a wafer.

### DETAILED DESCRIPTION OF THE INVENTION

Hereinafter, embodiments of a dicing groove inspecting method and a dicing method will be described with reference to the accompanying drawings.

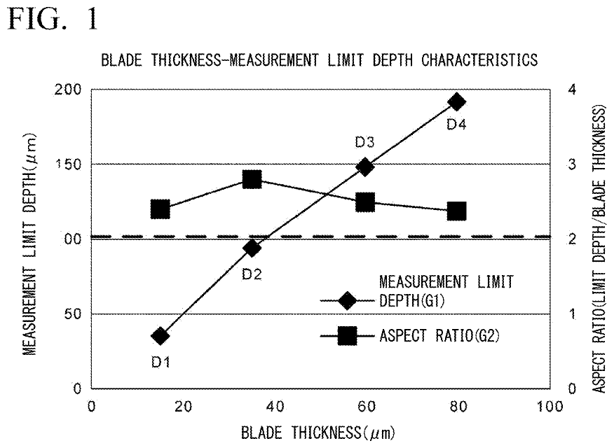

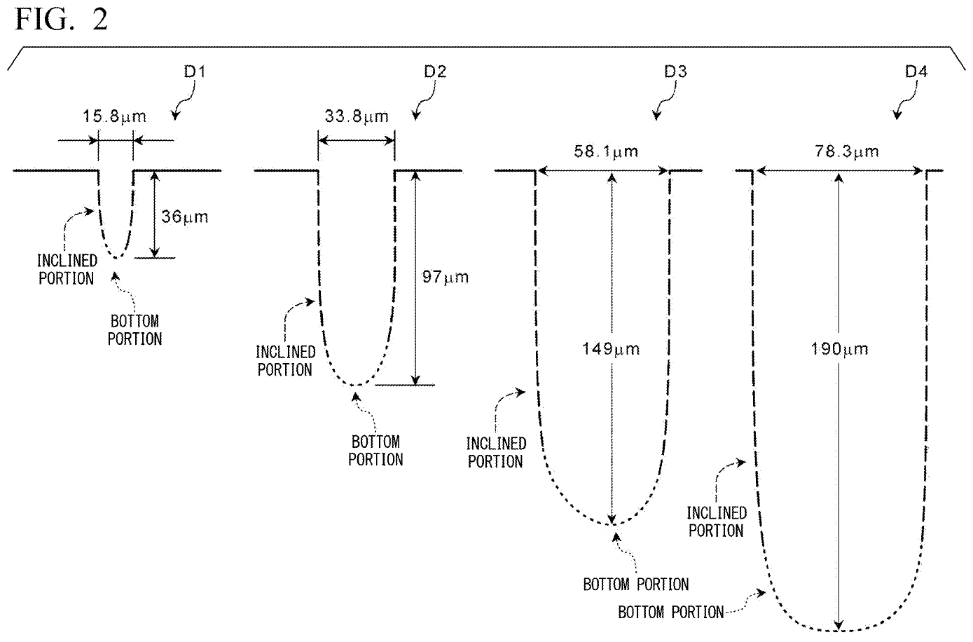

FIG. 1 is a graph showing characteristics of a blade thickness of a blade and a measurement limit depth inside a groove formed on a wafer and FIG. 2 is a diagram showing the blade thickness of the blade and a measurement limit investigation result inside the groove formed on the wafer.

Grooves with different widths and depths were formed on a mirror wafer with a high surface reflectance by blades with different blade thicknesses and the maximum depth value capable of measuring (observing) the inside of the groove (the inclined portion and the bottom portion) by the observation unit was investigated. Furthermore, in FIG. 1, the maximum depth value capable of measuring the inside of the groove by the observation unit is referred to as the measurement limit depth. A white interference microscope (“Opt-scope” (registered trademark) manufactured by Tokyo Seimitsu Co., Ltd.) was used as an observation unit for measuring the grooves shown in FIG. 1. The numerical aperture of the objective lens used to measure the grooves in FIG. 1 is NA=0.55, and the magnification is 50 times.

As shown in FIG. 2, the relationship between the blade thickness and the measurement limit depth is as below.
D1: blade thickness of 15.8 μm, depth of 36 μm
D2: blade thickness of 33.8 μm, depth of 97 μm
D3: blade thickness of 58.1 μm, depth of 149 μm
D4: blade thickness of 78.3 μm, depth of 190 μm

Graph G1 of FIG. 1 is a plot of data D1 to D4 in FIG. 2. Further, Graph G2 of FIG. 1 shows the ratio (aspect ratio) of the measurement limit depth to the blade thickness.

As shown in Graph G1, the measurable limit depth becomes deeper as the blade thickness becomes thicker, that is, the width of the groove becomes wider. Then, as shown in Graph G2, the blade thickness, that is, the aspect ratio which is the ratio of the measurement limit depth with respect to the width of the groove on the surface of the wafer W is 2 or more (above the dashed line of FIG. 1). That is, in the above-described example, the measurement limit depth is approximately twice the blade thickness and it can be seen that the inside of the groove can be measured if the depth of the groove is equal to or smaller than twice the blade thickness.

In this case, for example, when performing half cutting with a blade with a blade thickness of 30 μm and performing full cutting inside a groove formed by the half cutting, the full-cut groove may not be recognized if the set value of the processing depth of the half-cut groove exceeds 60 μm.

Therefore, in this embodiment, an inspection groove with a depth which can be measured by an observation unit, for example, a white interference microscope, that is, a groove which is shallower than the measurement limit depth is formed on the wafer by test cutting (mock-up processing). Here, the depth of the inspection groove is determined on the basis of the aspect ratio. Then, the groove formation results (for example, width and position, occurrence of chipping, and the like) for the groove actually formed on the wafer by the test cutting are inspected.

Then, the wafer is processed while removing the grooves formed through the test cutting by processing the wafer to the original processing depth (hereinafter, referred to as main processing). Accordingly, it is possible to accurately measure the groove formation results before the wafer processing even when forming the deep groove relative to the width, that is, even in the case of a high aspect ratio. Accordingly, it is possible to feed back the groove formation results to the processing to the original processing depth and to improve the wafer processing quality.

Furthermore, in the measurement results of FIGS. 1 and 2, the aspect ratio which is the ratio of the measurement limit depth to the blade thickness was 2 or more, but this is just an example. The aspect ratio may vary depending on factors such as the specifications of the objective lens used to observe the grooves (for example, NA or magnification) or the amount of illumination used to observe the grooves (for example, the maximum light amount). This embodiment can also be applied when using a measurement device other than the above-described white interference microscope by obtaining the aspect ratio of the interference optical system, illumination optical system, or the like used for groove measurement in advance through experiments.

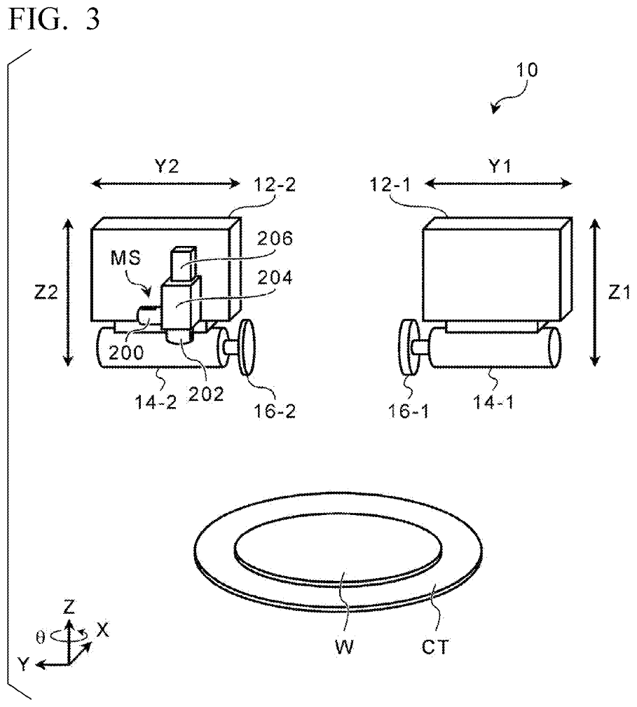

FIG. 3 is a perspective view showing a dicing device (blade dicer) according to the first embodiment of the present invention. Hereinafter, a description will be made using a three-dimensional orthogonal coordinate system in which the table CT is parallel to the XY directions and perpendicular to the Z direction.

As shown in FIG. 3, a dicing device 10 according to this embodiment includes a cutting unit 12 (a first cutting unit 12-1 and a second cutting unit 12-2) which performs a dicing process on a wafer W and the table CT. Furthermore, in the following description, the configuration common to two cutting units 12-1 and 12-2 will be described with branch numbers omitted.

The table CT has a holding surface parallel to the XY plane. The table CT holds the wafer W on this holding surface by suction using a vacuum source (a vacuum generator, for example, an ejector, a pump, and the like) not shown in the drawings. The wafer W is attached to a frame (not shown) via a dicing tape (not shown) having an adhesive layer of an adhesive formed on its surface, and is held by suction on the table CT. Furthermore, the frame to which the dicing tape is attached is held by frame holding means (not shown) provided on the table CT. Furthermore, a wafer transportation form that does not use a frame may be used.

The table CT is attached to a θ table (not shown), and the θ table is rotatable in the 0 direction (around a rotation axis centered on the Z axis) by a rotation drive unit including a motor and the like. The θ table is placed on an X table (not shown). The X table is movable in the X direction by an X drive unit including, for example, a motor and a ball screw.

The first cutting unit 12-1 and the second cutting unit 12-2 are respectively attached to a Z1 table and a Z2 table. The Z1 table and the Z2 table respectively are movable in the Z1 and Z2 directions by a Z drive unit including a motor and a ball screw. A Y1 table and a Y2 table are respectively attached to the Z1 table and the Z2 table. The Y1 table and the Y2 table are respectively movable in the Y1 and Y2 directions by a Y drive unit including a motor and a ball screw. The first cutting unit 12-1 and the second cutting unit 12-2 are examples of a processing unit.

Furthermore, in this embodiment, a configuration including a motor, a ball screw, and the like is used as the X drive unit, Y drive unit, and Z drive unit, but the present invention is not limited thereto. As the X drive unit, the Y drive unit, and the Z drive unit, for example, an air guide mechanism in which a gas bearing is provided between a guide shaft and a slider or a linear reciprocating mechanism such as a rack and pinion mechanism can be used.

As shown in FIG. 3, the first cutting unit 12-1 includes a first spindle 14-1 and a first blade 16-1. The second cutting unit 12-2 includes a second spindle 14-2 and a second blade 16-2. This example shows a case in which there is one table CT, but a configuration with multiple tables CT is also possible.

The first blade 16-1 and the second blade 16-2 are, for example, disc-shaped cutting blades. The first blade 16-1 is, for example, a surface blade which is a blade for removing a surface layer (hereinafter, sometimes referred to as an upper layer) of the wafer W, for example, a device layer. The second blade 16-2 is, for example, a silicon blade which is a blade for cutting (dividing) a layer located below the upper layer (hereinafter, sometimes referred to as a lower layer) of the wafer W, for example, a silicon layer. In the example shown in FIG. 3, the thickness of the first blade 16-1 is thicker than the thickness of the second blade 16-2. As the first blade 16-1 and the second blade 16-2, for example, an electrodeposited blade in which diamond abrasive grains or CBN (Cubic Boron Nitride) abrasive grains are electrodeposited with nickel or a resin blade bonded with resin can be used. The first blade 16-1 and the second blade 16-2 can be replaced depending on the type and size of the wafer W to be processed, the processing content, and the like.

The first blade 16-1 and the second blade 16-2 are respectively attached to the tips of the first spindle 14-1 and the second spindle 14-2. The first spindle 14-1 and the second spindle 14-2 include high-frequency motors for respectively rotating the first blade 16-1 and the second blade 16-2 at a high speed.

With the above-described configuration, the first blade 16-1 and the second blade 16-2 are respectively index-fed in the Y1 direction and the Y2 direction of the Y direction and cut-fed in the Z1 direction and the Z2 direction of the Z direction. Further, the table CT is rotated in the θ direction and fed for cutting in the X direction.

An observation unit MS is attached to the side surface of the second cutting unit 12-2 and is movable integrally with the second cutting unit 12-2. The observation unit MS photographs (observes) an image of the surface of the wafer W held by suction on the table CT. The observation unit MS includes, for example, a white interference microscope.

As shown in FIG. 3, the observation unit MS includes a light source section 200, an interference lens 202, a microscope 204, and a camera 206.

The light source section 200 emits a parallel beam of white light (low coherent light with little coherence) under the control of a control device 100. This light source section 200 includes a light source capable of emitting white light, such as a light emitting diode, a semiconductor laser, a halogen lamp, and a high-intensity discharge lamp and a collector lens which converts the white light emitted from this light source into a parallel beam of light. Furthermore, in the above-described example, white light is used, but illumination light other than white light (for example, monochromatic illumination light (high coherent light), green monochromatic light, and the like) may be used.

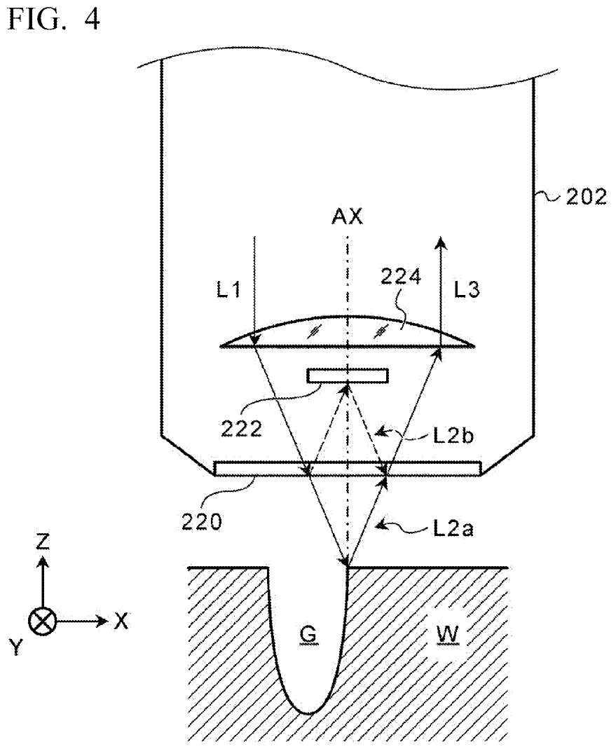

As shown in FIG. 4, the interference lens 202 includes a beam splitter 220, a reference surface 222, and an objective lens 224. Furthermore, FIG. 4 describes an example of a Mirau type interference optical system, but the present invention is not limited thereto. For example, it is also possible to employ other interference optical systems such as a Michelson type or a Linic type in the observation unit MS (for example, the interference lens 202).

As shown in FIG. 4, the beam splitter 220 and the objective lens 224 are arranged in order from the surface of the wafer W along the upper side in the Z direction and the reference surface 222 is disposed at a position facing the beam splitter 220 (a position between the beam splitter 220 and the objective lens 224).

The objective lens 224 has a light focusing function and focuses white light L1 incident from the light source section 200 onto the wafer W through the beam splitter 220.

The beam splitter 220 splits a part of the white light L1 incident from the objective lens 224 as reference light L2b, transmits remaining measurement light L2a to be emitted to the wafer W, and reflects the reference light L2b toward the reference surface 222. The measurement light L1a transmitted through the beam splitter 220 is irradiated onto the wafer W and then is reflected by the wafer W to return to the beam splitter 220.

For example, a reflecting mirror is used for the reference surface 222 and reflects the reference light L2b incident from the beam splitter 220 toward the beam splitter 220. The position of this reference surface 222 in the X direction can be manually adjusted by a position adjusting mechanism (for example, a ball screw mechanism, an actuator, and the like). Accordingly, the optical path length (reference optical path length) of the reference light L2b between the beam splitter 220 and the reference surface 222 can be adjusted. This reference optical path length is adjusted to match (including substantially match) the optical path length (measurement optical path length) of the measurement light L1 between the beam splitter 220 and the wafer W.

The measurement light L2a returning from the wafer W and the reference light L2b returning from the reference surface 222 are combined by the beam splitter 220 and reach the objective lens 224 as combined light L3.

The combined light L3 is transmitted through the objective lens 224 and then is imaged by the microscope 204 on the imaging plane of the camera 206. Specifically, the combined light L3 forms a point on the focal plane of the objective lens 224 as an image point on the imaging plane of the camera 206.

The camera 206 includes a CCD (Charge Coupled Device) type or a CMOS (Complementary Metal Oxide Semiconductor) type photographing element. The camera 206 photographs the combined light L3 focused on the imaging plane, processes an imaging signal of the combined light L3 obtained by this photographing, and outputs a photographed image. The observation unit MS measures the inside of the groove G by photographing the wafer W with the camera 206.

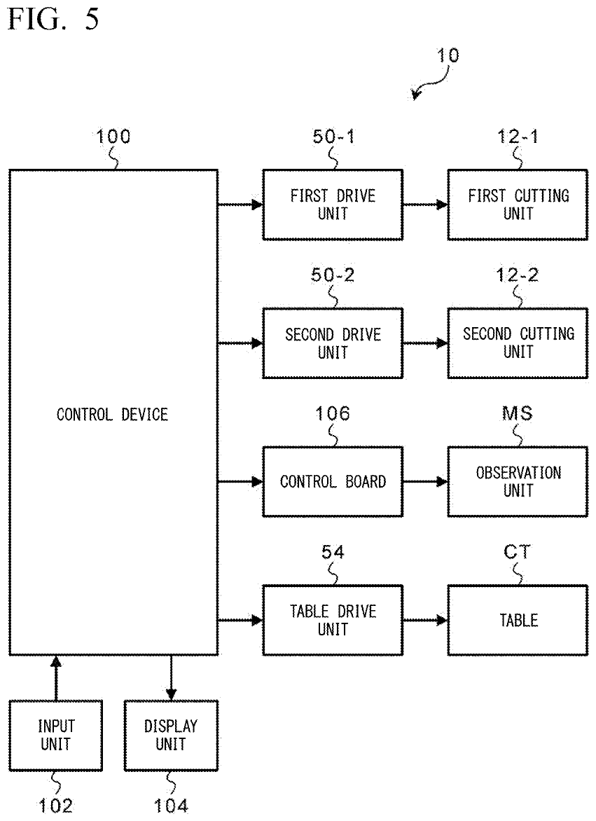

FIG. 5 is a block diagram showing a control system of a dicing device according to the first embodiment of the present invention.

As shown in FIG. 5, the control system of the dicing device 10 includes the control device 100, an input unit 102, a display unit 104, a first cutting unit 12-1, a second cutting unit 12-2, a first drive unit 50-1, a second drive unit 50-2, a table drive unit 54, and the table CT.

The control device 100 includes a CPU (Central Processing Unit), a ROM (Read Only Memory), a RAM (Random Access Memory), and a storage device (for example, HDD (Hard Disk Drive) or SSD (Solid State Drive)). The control device 100 controls each part of the dicing device 10. Furthermore, the control device 100 is, for example, a personal computer or a microcomputer.

The input unit 102 includes an operation unit (for example, a keyboard, a pointing device, and the like) for receiving an operation input from a user.

The display unit 104 displays a GUI (Graphical User Interface) and the like for operating the dicing device 10. The display unit 104 includes, for example, a liquid crystal display.

Each of the first drive unit 50-1 and the second drive unit 50-2 includes a power source (for example, a linear motor or a motor drive mechanism) for moving the first cutting unit 12-1 and the second cutting unit 12-2 in the YZ direction. As a mechanism for moving the first drive unit 50-1 and the second drive unit 50-2, for example, a mechanism capable of reciprocating linear motion, such as a ball screw or a rack and pinion mechanism can be used.

The observation unit MS is movable integrally with the second cutting unit 12-2 and is movable in the Z direction which is the scanning direction by the second drive unit 50-2. Furthermore, the observation unit MS may be movable independently of the second cutting unit 12-2.

The table drive unit 54 includes an X drive unit and a rotation drive unit for moving the table CT.

Furthermore, in this embodiment, the first cutting unit 12-1 and the second cutting unit 12-2 are moved in the YZ directions to move the table CT in the Xθ directions, but the present invention is not limited thereto. For example, the table CT may be movable in the YZ direction. That is, any configuration may be used if the first cutting unit 12-1 and the second cutting unit 12-2 are movable relative to the table CT in the XYZθ directions.

Further, the number of tables CT is not limited to one, but may be provided in multiple numbers. When the dicing device 10 includes the plurality of tables CT, the dicing process may be performed in the other table CT while the observation unit MS in one table CT performs measurement in a state in which the observation units MS are driven independently. Although it requires scanning time for the measurement using the observation unit MS such as a white interference microscope, it is possible to reduce working time by enabling processing and measurement to be performed in parallel on the plurality of tables CT.

As described above, in this embodiment, the groove of the depth which can be measured by the white interference microscope, that is, the groove which is shallower than the measurement limit depth is formed on the wafer by the test cutting and the groove formation results (for example, width and position, occurrence of chipping, and the like) are inspected. Then, the wafer is processed while removing the grooves formed through the test cutting by performing main processing on the wafer to the original processing depth.

First, an example of performing step cutting will be described. When performing the step cutting by the dicing device 10, two blades with different blade thicknesses are used. In this embodiment, as the first blade 16-1, one having a blade thickness thicker than that of the second blade 16-2 is used.

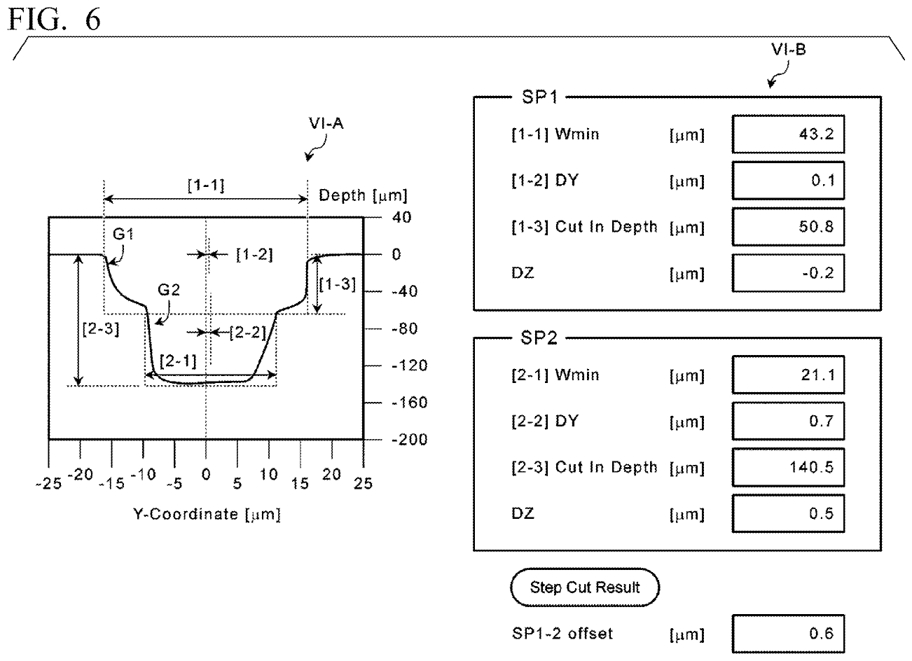

FIG. 6 is a diagram showing an output example of a groove inspection result by the step cutting. VI-A of FIG. 6 shows an output example of the measurement result of the inside shape (cross-sectional shape) of grooves G1 and G2 respectively formed by the first blade 16-1 and the second blade 16-2. In VI-A of FIG. 6, the depth coordinate of the surface of the wafer W is Z=0. The direction (width direction) perpendicular to the groove formation direction is the Y direction and Y=0 is the center position of the camera 206. On the other hand, VI-B of FIG. 6 shows an output example of numerical values of the inside shapes of the grooves G1 and G2 in VI-A in FIG. 6.

In FIG. 6, Wmin in [1-1] and [2-1] is the width of each of the groove G1 and the groove G2 and corresponds to the blade thickness of each of the first blade 16-1 and the second blade 16-2.

DY in [1-2] and [2-2] is the offset amount (the offset amount in the Y direction) of the center lines of the groove G1 and the groove G2 from the center (Y=0) of the camera 206 and corresponds to the offset amount of the first spindle 14-1 (SP1) and the second spindle 14-2 (SP2) from the center of the camera 206.

Cut In Depth in [1-3] and [2-3] is the depth of each of the groove G1 and the groove G2. DZ is the offset amount (the offset amount in the Z direction) of the depth measurement values of the groove G1 and the groove G2 with respect to the Cut In Depth set values of [1-3] and [2-3]. In this embodiment, the DZ correction amount is obtained so that the cutting amount of each of the first spindle 14-1 (SP1) and the second spindle 14-2 (SP2) becomes a target value. In the example shown in FIG. 6, the target value of the cutting amount of SP1 is 51 μm as an example and the target value of the cutting amount of SP2 is 140 μm as an example.

SP1-2 offset of VI-B of FIG. 6 is the offset amount (the offset amount in the Y direction) of the center lines of the groove G1 and the groove G2 and corresponds to the offset amount of the first spindle 14-1 (SP1) and the second spindle 14-2 (SP2).

When measuring the step cutting result, the formation result of the groove G2 formed inside the groove G1 is measured. Therefore, the depth of the groove G1 is determined by the aspect ratio of the observation unit MS obtained in advance through experiments. Specifically, the depth of the groove G1 is set to be equal to or smaller than twice the width of the groove G1, that is, the blade thickness of the first blade 16-1.

Then, the cutting unit adjustment work for the position and the movement amount of the first spindle 14-1 (SP1) and the second spindle 14-2 (SP2) in the YZ directions are performed on the basis of the measurement results of the grooves G1 and G2 formed by the test cutting of the step cutting. Then, the wafer is processed to the original processing depth after the above-described adjustment work.

As the cutting unit adjustment work, for example, at least one of the works listed below is performed.
(1) The Y-direction position of the second spindle 14-2 (SP2) is adjusted so that SP1-2 offset becomes zero.
(2) A display of prompting the user to replace the first blade 16-1 and the second blade 16-2 is performed depending on the occurrence of chipping.
(3) The Y-direction position of the second spindle 14-2 (SP2) is adjusted so that DY of the second spindle 14-2 (SP2) becomes zero.
(4) The Z-direction movement amount of the second spindle 14-2 (SP2) is adjusted so that DZ of the second spindle 14-2 (SP2) becomes zero.

As described above, it is possible to perform the main processing of the wafer W with high precision by performing the adjustment work on the basis of the test cutting result.

Furthermore, it is also possible to adjust the Y-direction position and the Z-direction movement amount of the first spindle 14-1 (SP1) in addition to the second spindle 14-2 (SP2).

As the adjustment of the Y-direction position and the Z-direction movement amount of the first spindle 14-1 (SP1), for example, at least one of the works listed below is performed.
(5) The Y-direction positions of the first spindle 14-1 (SP1) and the second spindle 14-2 (SP2) are adjusted so that the offset amount DY of the center lines of the groove G1 and the groove G2 with respect to the center of the camera 206 becomes 0 μm.
(6) The Y-direction position of the first spindle 14-1 (SP1) is adjusted so that DY of the first spindle 14-1 (SP1) becomes zero.
(7) The Z-direction movement amount of the first spindle 14-1 (SP1) is adjusted so that DZ of the first spindle 14-1 (SP1) becomes zero.

As described above, it is possible to perform the main processing of the wafer W with high precision by performing the adjustment work for the first cutting unit 12-1 and the second cutting unit 12-2 on the basis of the test cutting result.

### Example 1

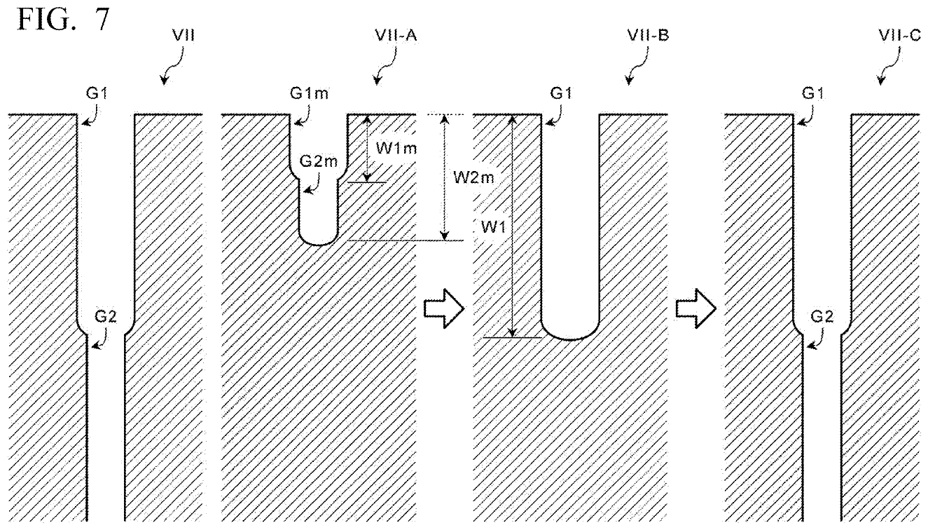

Example 1 (FIG. 7) shows an example in which step cutting is performed by a blade dicing process. VII of FIG. 7 shows a state in which the wafer W is divided by the step cutting, that is, the main processing of the wafer W is completed.

In this example, as described above, the wafer is processed to the original processing depth after performing the test cutting to the depth according to the aspect ratio of the observation unit MS.

First, test cutting (mock-up processing) of the wafer W is performed as indicated by VII-A of FIG. 7. In the test cutting, first, a groove G1m (first inspection groove) is formed on the wafer W by the first blade 16-1. Next, a groove G2m (second inspection groove) which is deeper than the groove G1m is formed inside the groove G1m by the second blade 16-2 having a blade thickness thinner than the first blade 16-1. Here, a depth W1m of the groove G1m of the test cutting is set to be shallower than the measurement limit depth according to the aspect ratio of the observation unit MS. Accordingly, the groove G2m formed inside the groove G1m can be measured.

Next, the cutting unit adjustment work is performed on the basis of the measurement result inside the groove G1m including the recognition result of the groove G2m. Then, dicing grooves (the first groove G1 and the second groove G2) are formed by sequentially performing the step cutting (main processing) to the original processing depth as indicated by VII-B and VII-C of FIG. 7 after the cutting unit adjustment work.

Here, when forming the thick groove G1 in the main processing of the step cutting, a depth W1 of the groove G1 is set to be deeper than the groove G2m. Accordingly, since the grooves G1m and G2m formed by the test cutting are removed (reset) by the groove G1 of the main processing, uneven wear caused by the second blade 16-2 coming into contact with the groove G2m when cutting the groove G2 can be prevented.

Further, since the positions of the test cutting and the main processing overlap each other as described above, unnecessary movements of the drive shafts of the first spindle 14-1 and the second spindle 14-2 can be suppressed. Accordingly, it is possible to perform the main processing with high precision.

### Example 2

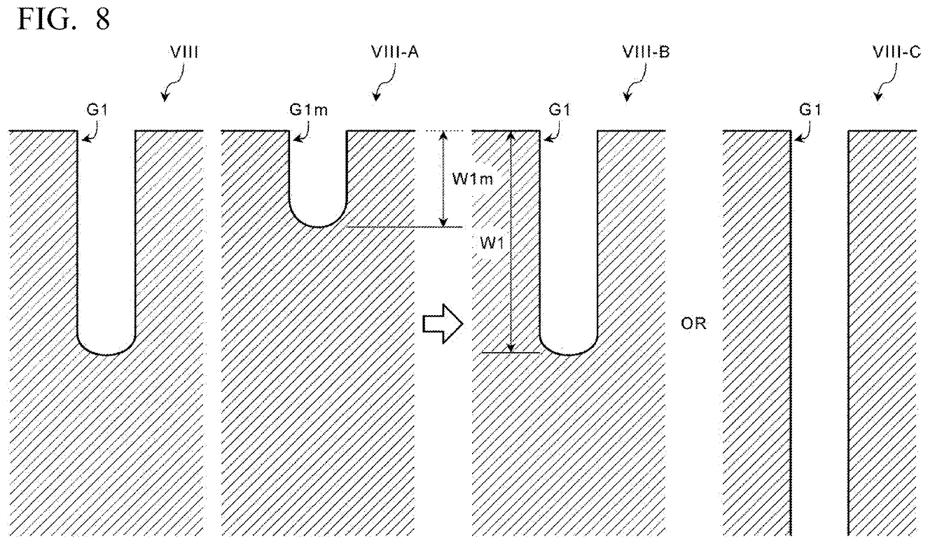

Example 2 (FIG. 8) shows an example in which the wafer W is processed by a blade dicing process (single blade). VIII of FIG. 8 indicates a state in which the groove G1 of the main processing is formed on the wafer W by the single blade, that is, the main processing of the wafer W is completed.

First, test cutting (mock-up processing) of the wafer W is performed as indicated by VIII-A of FIG. 8. In the test cutting, the groove G1m is formed on the wafer W by the first blade 16-1. Here, the depth W1m of the groove G1m of the test cutting is set to be shallower than the measurement limit depth according to the aspect ratio of the observation unit MS. Accordingly, it is possible to measure the inside of the groove G1m.

Next, the cutting unit adjustment work is performed on the basis of the measurement result inside the groove G1m. Then, the main processing of the wafer W is performed as indicated by VIII-B of FIG. 8 after the cutting unit adjustment work. Here, the depth W1 of the groove G1 formed by the main processing is set to be deeper than the depth W1 nm of the groove G1m. Accordingly, the groove G1m formed by the test cutting is removed (reset) by the groove G1 of the main processing. Although the above shows an example of the single blade using the first blade 16-1 (SP1), the inspection method according to this embodiment can also be applied to a case in which processing is performed only by the second blade 16-2 (SP2). Further, the inspection method according to this embodiment can be applied similarly when processing individual Y-positions by the first blade 16-1 (SP1) and the second blade 16-2 (SP2).

Further, the wafer W may be completely divided by the main processing as indicated by VIII-C of FIG. 8.

Even in Example 2, it is possible to perform the main processing of the wafer W with high precision by performing the test cutting to the measurement limit depth according to the aspect ratio of the observation unit MS.

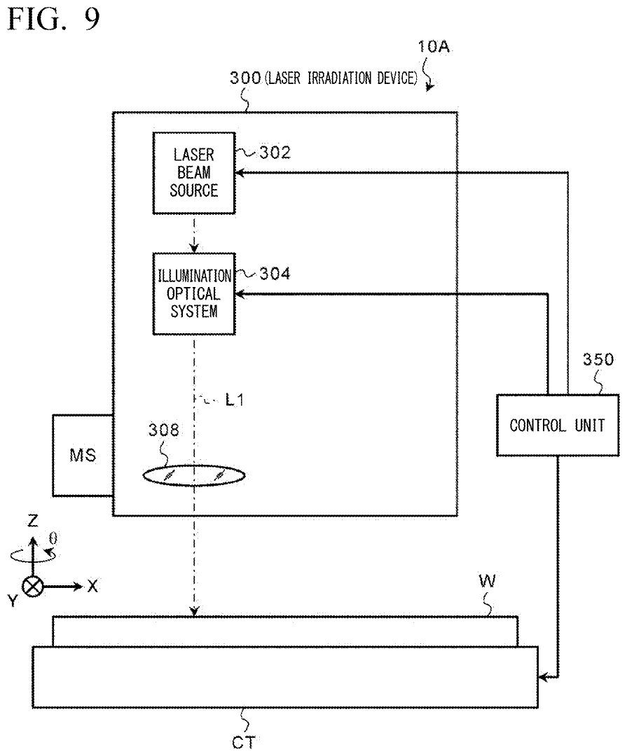

FIG. 9 is a block diagram showing a dicing device (laser dicer) according to a second embodiment of the present invention. Hereinafter, a description will be made using a three-dimensional orthogonal coordinate system in which a table CT is parallel to the XY directions and perpendicular to the Z direction.

A dicing device 10A is a device which processes the wafer W by laser grooving. As shown in FIG. 9, the dicing device 10A includes the table CT which moves the wafer W, a laser irradiation device 300 which irradiates the wafer W with laser beam, the observation unit MS, and a control unit 350 which controls each part of the dicing device 10A. Since the observation unit MS is the same as that of the first embodiment, a description thereof will be omitted.

The table CT is configured to be movable in the XYZθ directions with respect to the laser irradiation device 300, and holds the wafer W by suction. The wafer W is placed on the table CT with the surface (the side on which devices are formed) facing upward in the drawing. Furthermore, the table CT and the laser irradiation device 300 may be relatively movable in the XYZθ directions and a relative movement mechanism (for example, a mechanism capable of reciprocating linear motion including a motor and a ball screw or a rotational drive mechanism including a motor) may move at least one of the table CT and the laser irradiation device 300 relative to the other in the XYZθ directions.

The laser irradiation device 300 is disposed at a position facing the wafer W and irradiates the wafer W with processing laser beam L1 for forming grooves (G1, G2) on the wafer W. That is, the laser irradiation device 300 is an example of the processing unit.

The control unit 350 includes a CPU (Central Processing Unit), a memory, a storage device, an input/output circuit, and the like and stores data necessary for operating and processing each part of the dicing device 10A.

The dicing device 10A also includes a wafer suction means, a wafer conveyance means, an operation panel, a monitor, an indicator light, and the like (not shown).

The operation panel is equipped with switches and display devices that operate the operations of each part of the dicing device 10A. The TV monitor displays a wafer image captured by a CCD (Charge Coupled Device) camera (not shown), program contents, various messages, and the like. The indicator light indicates the operating status of the dicing device 10A, such as a processing state, a processing end state, and an emergency stop state.

Next, the detailed configuration of the laser irradiation device 300 will be described. As shown in FIG. 9, the laser irradiation device 300 includes a laser beam source 302, an illumination optical system 304, and a condensing lens 308.

The laser beam source 302 emits processing laser beam (hereinafter, also referred to as laser beam) L1 for forming grooves (G1, G2) on the surface of the wafer W.

The illumination optical system 304 and the condensing lens 308 are sequentially arranged on the first optical path of the processing laser beam L1 from the laser beam source 302.

The processing laser beam L1 emitted from the laser beam source 302 passes through the illumination optical system 304 and then is condensed onto the surface of the wafer W by the condensing lens 308. Laser ablation processing of the wafer W is performed by this processing laser beam L1. The Z-direction position of the condensing point of the processing laser beam L1 may be adjusted by slightly moving the condensing lens 308 in the Z direction using an actuator (not shown).

The control unit 350 can keep the distance between the condensing lens 308 and the surface of the wafer W in a predetermined relationship (so that the distance is constant) using an actuator (not shown).

Even in this embodiment, an adjustment work for the laser irradiation device 300 (processing unit) is performed on the basis of the groove detection result of the observation unit MS. Specifically, the adjustment work includes adjusting the numerical aperture or magnification of the condensing lens 308 and adjusting the spot diameter of the processing laser beam L1.

Furthermore, the illumination optical system 304 may shape the spot of the laser beam L1 on the surface of the wafer W into an oval shape (for example, an ellipse or an oval) or a rectangle in which one diameter is longer than the other diameter. Such a spot shape can be formed, for example, by including an oval lens or a cylindrical lens in the illumination optical system 304. When the illumination optical system 304 is rotated around the Z axis using a lens drive mechanism (not shown), the width of the spot of the laser beam L1 in the Y direction changes. Accordingly, step cutting can be performed with a laser dicer (ablation dicer) in the same way as the blade dicer shown in FIG. 3. Thus, the processing described in Examples 1 and 2 can also be performed using the laser dicer.

### Example 3

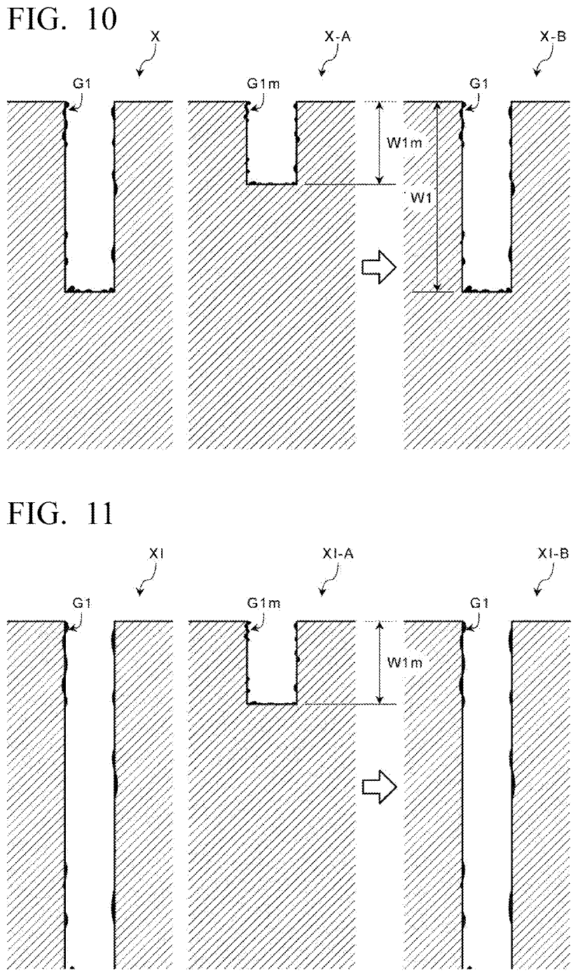

Example 3 (FIG. 10) shows an example in which the wafer W is processed by a laser grooving process. X of FIG. 10 indicates a state in which the groove G1 is formed on the wafer W by the laser grooving process, that is, the main processing of the wafer W is completed.

First, test cutting (mock-up processing) of the wafer W is performed as indicated by X-A of FIG. 10. In the test cutting, the groove G1m is formed on the wafer W by laser grooving. Here, the depth W1m of the groove G1m of the test cutting is set to be shallower than the measurement limit depth according to the aspect ratio of the observation unit MS. Accordingly, it is possible to measure the inside of the groove G1m.

Next, an adjustment work for the laser irradiation device 300 is performed on the basis of the measurement result inside the groove G1m. Then, the main processing of the wafer W is performed as indicated by X-B of FIG. 10 after the adjustment work for the laser irradiation device 300. Here, the depth W1 of the groove G1 formed by the main processing is set to be deeper than the depth W1m of the groove G1m. Accordingly, the groove G1m formed by the test cutting is removed (reset) by the groove G1 of the main processing.

Even in Example 3, it is possible to perform the main processing of the wafer W with high precision by performing the test cutting to the measurement limit depth according to the aspect ratio of the observation unit MS.

### Example 4

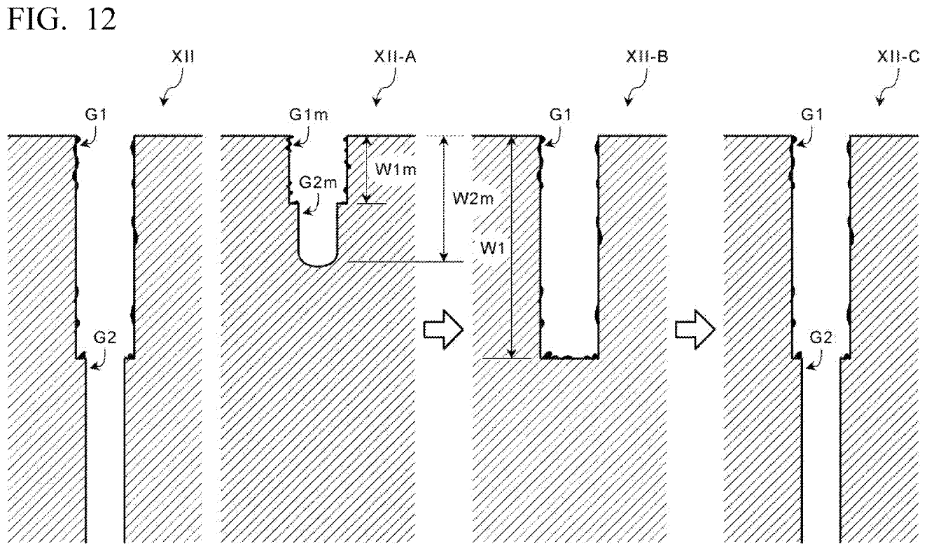

Example 4 (FIG. 11) shows an example in which the wafer W is processed by a laser grooving process. XI of FIG. 11 indicates a state in which the groove G1 is divided in the wafer W by the laser grooving process, that is, the main processing of the wafer W is completed.

First, test cutting (mock-up processing) of the wafer W is performed as indicated by XI-A of FIG. 11. In the test cutting, the groove G1m is formed on the wafer W by laser grooving. Here, the depth W1m of the groove G1m of the test cutting is set to be shallower than the measurement limit depth according to the aspect ratio of the observation unit MS. Accordingly, it is possible to measure the inside of the groove G1m.

Next, an adjustment work for the laser irradiation device 300 is performed on the basis of the measurement result inside the groove G1m. Then, the main processing of the wafer W is performed as indicated by XI-B of FIG. 11 after the adjustment work for the laser irradiation device 300. The wafer W is completely divided by the main processing.

Even in Example 4, it is possible to perform the main processing of the wafer W with high precision by performing the test cutting to the measurement limit depth according to the aspect ratio of the observation unit MS.

In the above-described embodiments, a case of processing the wafer W by the blade dicer or the laser dicer has been described, but the present invention can be also applied when performing the step cutting by combining the blade dicing and the laser grooving using a device including both the blade dicer and the laser dicer.

### Example 5

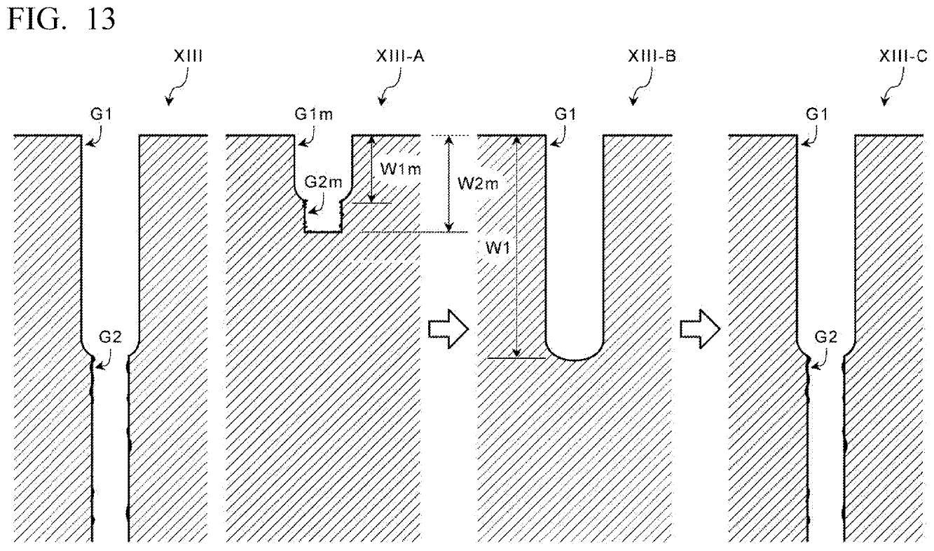

Example 5 (FIG. 12) shows an example of performing step cutting by combining blade dicing and laser grooving. XII of FIG. 12 indicates a state in which the wafer W is divided by the step cutting, that is, the main processing of the wafer W is completed.

First, test cutting (mock-up processing) of the wafer W is performed as indicated by XII-A of FIG. 12. In the test cutting, first, the groove G1m is formed on the wafer W by laser grooving. Next, the groove G2m which is deeper than the groove G1m is formed inside the groove G1m by a blade having a blade thickness thinner than the groove G1m. Here, the depth W1m of the groove G1m of the test cutting is set to be shallower than the measurement limit depth according to the aspect ratio of the observation unit MS. Accordingly, the groove G2m formed inside the groove G1m can be measured.

Next, an adjustment work for the laser irradiation device 300 is performed on the basis of the measurement result inside the groove G1m including the recognition result of the groove G2m. Then, the step cutting (main processing) is sequentially performed to the original processing depth as indicated by XII-B and XII-C of FIG. 12 after the adjustment work for the laser irradiation device 300.

Here, when forming the thick groove G1 in the main processing of the step cutting, the depth W1 of the groove G1 is set to be deeper than the groove G2m. Accordingly, since the grooves G1m and G2m formed by the test cutting is removed (reset) by the groove G1 of the main processing, uneven wear caused by the blade coming into contact with the groove G2m when cutting the groove G2 can be prevented.

### Example 6

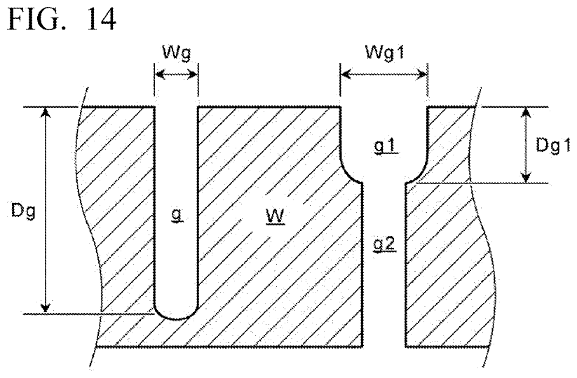

Example 6 (FIG. 13) shows another example of performing step cutting by combining blade dicing and laser grooving. XIII of FIG. 13 indicates a state in which the wafer W is divided by the step cutting, that is, the main processing of the wafer W is completed.

First, test cutting (mock-up processing) of the wafer W is performed as indicated by XIII-A of FIG. 13. In the test cutting, first, the groove G1 nm is formed on the wafer W by a blade. Next, the groove G2m which is narrower and deeper than the groove G1m is formed inside the groove G1m by laser grooving. Here, the depth W1m of the groove G1m of the test cutting is set to be shallower than the measurement limit depth according to the aspect ratio of the observation unit MS. Accordingly, the groove G2m formed inside the groove G1m can be measured.

Next, an adjustment work for the laser irradiation device 300 is performed on the basis of the measurement result inside the groove G1m including the recognition result of the groove G2m. Then, the step cutting (main processing) is sequentially performed to the original processing depth as indicated by XIII-B and XIII-C of FIG. 13 after the adjustment work for the laser irradiation device 300.

Here, when forming the thick groove G1 in the main processing of the step cutting, the depth W1 of the groove G1 is set to be deeper than the groove G2m. Accordingly, the groove G1m and G2m formed by the test cutting are removed (reset) by the groove G1 of the main processing.

Even in Examples 5 and 6, it is possible to perform the main processing of the wafer W with high precision by performing the test cutting to the measurement limit depth according to the aspect ratio of the observation unit MS.

Furthermore, in the above-described embodiments, an example including the white interference microscope as the observation unit MS has been described, but the observation unit MS is not limited thereto. For example, the observation unit MS may also serve as a shape detection microscope used for shape detection. For example, the observation unit MS may also serve as a shape detection microscope used for shape detection or the alignment observation unit and the white interference microscope may be mounted as separate units and driven individually.

### EXPLANATION OF REFERENCES

10 Dicing device (blade dicer)
12-1 First cutting unit
12-2 Second cutting unit
14-1 First spindle
14-2 Second spindle
16-1 First blade
16-2 Second blade
CT Table
50-1 First drive unit
50-2 Second drive unit
MS Observation unit
54 Table drive unit
100 Control device
102 Input unit
104 Display unit
106 Control board
10A Dicing device (laser dicer)
300 Laser irradiation device
302 Laser beam source
304 Illumination optical system
308 Condensing lens
350 Control unit

What is claimed is:

1. A dicing groove inspecting method comprising:
forming an inspection groove by performing test cutting on a wafer using a dicing device equipped with an observation unit such that the inspection groove having a depth equal to or smaller than a measurement limit depth capable of measuring the inside of the inspection groove by the observation unit is formed on the wafer; and
measuring the inside of the inspection groove formed on the wafer by the test cutting using the observation unit.

2. The dicing groove inspecting method according to claim 1,
wherein a depth of the inspection groove formed by the test cutting is determined according to an aspect ratio obtained in advance for the observation unit and corresponding to a ratio of the measurement limit depth to a width of the groove on the surface of the wafer.

3. A dicing method of performing an adjustment work for the dicing device on the basis of a result obtained by measuring the inside of the inspection groove using the dicing groove inspecting method according to claim 1 and forming a dicing groove at a position of the wafer overlapping the inspection groove by main processing of the wafer.

4. The dicing method according to claim 3,
wherein a depth of the groove formed by the main processing is deeper than a depth of the inspection groove.

5. The dicing method according to claim 3,
wherein when a first groove and a second groove which is narrower and deeper than the first groove are sequentially formed on the wafer in the main processing, the inspection groove includes a first inspection groove which has the same width as that of the first groove and has a depth equal to or smaller than the measurement limit depth according to a width of the first groove and a second inspection groove which has the same width as that of the second groove and is deeper than the first inspection groove,
wherein the first groove formed by the main processing of the wafer is formed to overlap the first inspection groove, and
wherein a depth of the first groove is deeper than the second inspection groove.
